(19) United States
(12) Patent Application Publication
(10) Pub. No.: US 2023/0090230 A1
(43) Pub. Date: Mar. 23, 2023

(54) HEAT RADIATION DEVICE AND ELECTRONIC EQUIPMENT

(71) Applicant: CASIO COMPUTER CO., LTD., Tokyo (JP)

(72) Inventor: Kiyohiko INOUE, Sagamihara-shi (JP)

(73) Assignee: CASIO COMPUTER CO., LTD., Tokyo (JP)

(21) Appl. No.: 17/950,616

(22) Filed: Sep. 22, 2022

(30) Foreign Application Priority Data
Sep. 22, 2021 (JP) 2021-153710
Mar. 24, 2022 (JP) 2022-047912

(51) Int. Cl. H05K 7/20

(52) U.S. Cl. CPC H05K 7/2039; H05K 7/20336

(57) ABSTRACT

Disclosed is a heat radiation device including: a heat receiver configured to be in contact with a heat radiation target; a heat radiator that radiates heat into air; and a heat pipe that transfers heat from the heat receiver to the heat radiator. The heat pipe includes a bend that bends in a direction away from the heat radiation target. The heat receiver includes a section that follows at least part of the bend and is in contact with the bend.

### REFERENCE TO RELATED APPLICATION

The present application claims the benefit of priority of Japanese Patent Application No. 2021-153710 filed on Sep. 22, 2021 and Japanese Patent Application No. 2022-47912 filed on Mar. 24, 2022, the entire contents of Japanese Patent Application No. 2021-153710 and Japanese Patent Application No. 2022-47912 are incorporated herein by reference.

### BACKGROUND OF THE INVENTION

### Field of the Invention

The present disclosure relates to a heat radiation device and an electronic equipment.

### Description of the Related Art

While various electronic components that operate in electronic equipment generate heat as they operate, the electronic components can be adversely affected by temperature changes. Therefore, there are heat radiation devices that quickly release the generated heat from the electronic component concerned. JP 2001-251079 A discloses a technology to save space without reducing the efficiency of heat transport by twisting and folding a flat heat pipe that connects the heat receiving part in contact with the electronic equipment to the heat radiation fin that releases heat efficiently.

### SUMMARY OF THE INVENTION

According to an aspect of the present disclosure, there is provided a heat radiation device including: a heat receiver configured to be in contact with a heat radiation target; a heat radiator that radiates heat into air; and a heat pipe that transfers heat from the heat receiver to the heat radiator, wherein the heat pipe includes a bend that bends in a direction away from the heat radiation target, and the heat receiver includes a section that follows at least part of the bend and is in contact with the bend.

### BRIEF DESCRIPTION OF THE DRAWINGS

The accompanying drawings are not intended as a definition of the limits of the disclosure but illustrate embodiments of the disclosure, and together with the general description given above and the detailed description of the embodiments given below, serve to explain the principles of the disclosure, wherein:

FIG. 1A is an external perspective view of an electronic equipment including a heat radiation device of a first embodiment;

FIG. 1B is a perspective view of the interior of the electronic equipment including the heat radiation device of the first embodiment;

FIG. 2A is a perspective view showing the structure of the heat radiation device of the first embodiment;

FIG. 2B is a lateral view showing the structure of the heat radiation device of the first embodiment;

FIG. 3A is a lateral view of a heat radiation device of a second embodiment;

FIG. 3B is a lateral view of a heat radiation device of a third embodiment;

FIG. 4A is a view for explaining a heat radiation device of a fourth embodiment;

FIG. 4B is a view for explaining a heat radiation device of a fifth embodiment;

FIG. 5A is a view for explaining an example of the cross section of the heat radiation device;

FIG. 5B is a view for explaining an example of the cross section of the heat radiation device;

FIG. 5C is a view for explaining an example of the cross section of the heat radiation device;

FIG. 5D is a view for explaining an example of the cross section of the heat radiation device; and

FIG. 5E is a view for explaining an example of the cross section of the heat radiation device.

### DETAILED DESCRIPTION OF THE PREFERRED EMBODIMENTS

Hereinafter, embodiments of the present disclosure will be described with reference to the drawings.

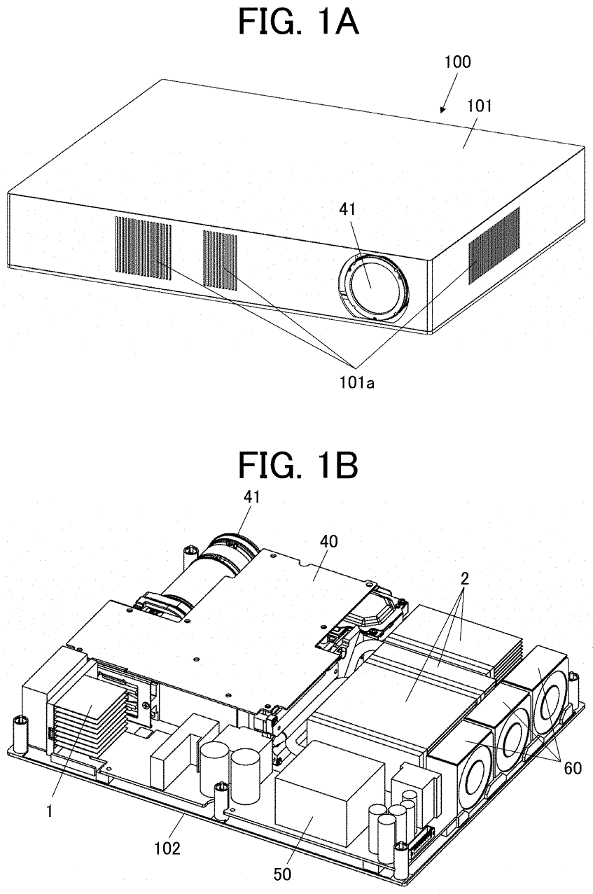

FIGS. 1A and 1B are views showing an electronic equipment 100 including a heat radiation device 1 in a first embodiment.

As shown in the external perspective view of FIG. 1A, the electronic equipment 100 is, for example, a projection device that projects an image by emitting light from an exit lens 41. The electronic equipment 100 has a cover member 101, support plate 102 and each component arranged on the support plate 102 (see FIG. 1B). The components are covered by a cover member 101 that is attached to said support plate 102. The cover member 101 has grid windows 101a for intake and/or exhaust.

FIG. 1B is a perspective view of the interior with the cover member 101 removed. FIG. 1B shows a view of the electronic equipment 100 shown in FIG. 1A, rotated 180 degrees in the mounting plane and viewed from behind at an angle to an emission direction of the exit lens 41.

On the support plate 102, an optical system 40 including the exit lens 41, a control circuit (processor) 50, and blowers 60 are lined up as the components. There are also heat radiation devices 1, 2 to radiate and release the heat which was generated/obtained mainly at the heat generating parts (mainly light-emitting elements and movable mirrors (Digital Micromirror Device; DMD)) of the control circuit 50 and the optical system 40. The heat radiation device 2 is large and radiates a large amount of heat. The heat radiation device 1 is small and radiates a relatively smaller amount of heat than the heat radiation device 2.

The optical system 40 has a light emitter, lens and mirrors for converging and guiding light, and switching elements (such as the DMD mentioned above) that switch the output of converged light for each pixel. The light emitter is, for example, LEDs and LDs (laser diodes), and LDs in particular tend to generate more heat than other parts. As the DMD operates, the light that is not output is scattered and absorbed in the optical system 40, and a part of these lights are converted to heat, heating the optical system 40. Accordingly, the optical system 40 is the main heat radiation target by the heat radiation devices 1, 2.

The control circuit 50 has a control IC and its associated electronic components and controls the operation of the optical system 40 (DMD) according to the projected image. Since the control IC and other components also generate heat as they operate, the control IC and other components can also be heat radiation targets of the heat radiation device 1 or the like.

The blowers 60 are here, for example, fans, which suck air around the heat radiator of the nearest heat radiation device 2 and blow the air out of the cover member 101 through the grid window 101a located in the immediate vicinity on the side opposite to the heat radiation device 2. New air flows in from outside the cover member 101 in response to the warm air that is blown out of the cover member 101 by the blowers 60. A portion of such new air flowing in from outside flows in through the other grid window 101a and passes around the heat radiator of the heat radiation device 1 to go to the blowers 60. For this purpose, the positional relationship between components (i.e., the gap that serves as the wind path) may be defined accordingly.

As shown above, it can be seen that the volume of the heat radiation devices 1 and 2 is too large to ignore, relative to the size of the electronic equipment 100. On the other hand, since it is undesirable to increase the size of electronic equipment 100 without limit, it is desirable to arrange and downsize the heat radiation devices 1 and 2 as efficiently as possible while ensuring their effectiveness.

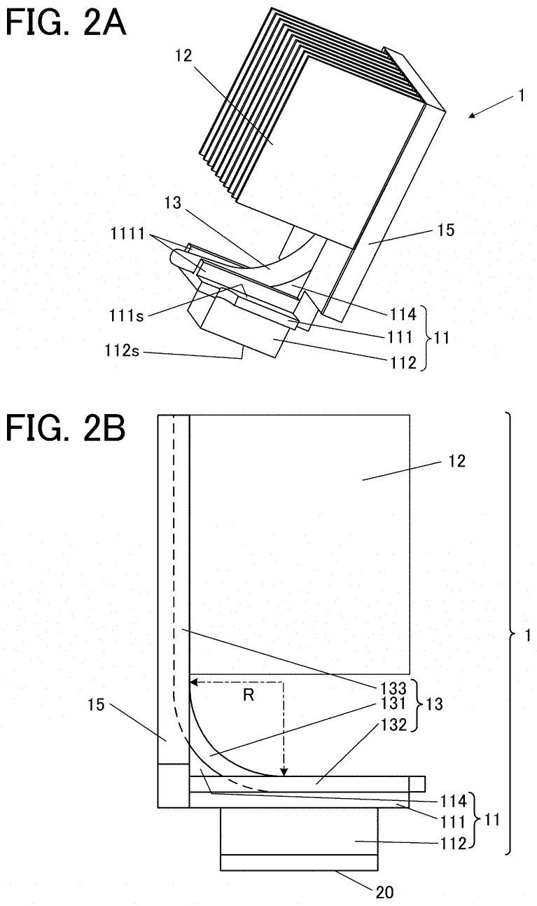

FIGS. 2A and 2B are views showing the structure of the heat radiation device 1 in the first embodiment. FIG. 2A is a perspective view and FIG. 2B is a lateral view seen from the side.

As shown in FIG. 2A, the heat radiation device 1 includes a heat receiver 11 that is in contact with the heat radiation target 20, a heat radiator 12 that radiates and releases heat into the air, a heat pipe 13 that transmits heat from the heat receiver 11 to the heat radiator 12, a support plate 15, etc.

The heat receiver 11 includes a base and a joint 114. The base in the embodiment has a heat transfer section 111 that is in a plate shape and a protruding section 112 protruding from the heat transfer section 111. The protruding surface 112s that is the surface opposite to the side of the heat transfer section 111 of the protruding section 112 is the contact surface that is in contact with the heat radiation target 20.

The base and the support plate 15 are conductor metals with high thermal conductivity, such as aluminum or copper materials with thermal conductivity exceeding 100 W/(m·K), respectively. The base is formed, for example, by aluminum die casting, in which molten metal such as aluminum alloy is pressed into a mold for instantaneous forming; extrusion, in which heated molten resin is extruded from a mold, cooled, and solidified for continuous forming; or cutting along an external shape. This makes the base an abbreviated rigid structure whose deformation is negligibly small compared to the basic shape. The heat receiver 11 is in contact with the heat radiation target 20 and the heat pipe 13, and heat generated by the heat generation target 20 is transferred to the heat pipe 13 via the heat receiver 11.

The heat radiator 12 radially releases (radiates) the heat received from the heat pipe 13 into the air. The heat radiator 12 has multiple conductor plates (heat radiation fins), and said heat radiation plates are aligned in parallel on the support plate 15 to increase the contact area with the air, thereby efficiently radiating heat. Though only a single heat pipe 13 is shown in the embodiment, multiple heat pipes 13 may be used. In this case, each of the heat pipes 13 may be connected to a different heat radiator 12 or may be connected to a common heat radiator 12. The heat radiator 12 is a conductive metal with high thermal conductivity, for example, aluminum or copper material. The material of heat radiator 12 may be the same as or different from the material of the base of the heat receiver 11.

It is desirable that the heat radiator 12 is located on the path of air flow by the blowers 60 as described above, but the heat radiation device 1 itself may be equipped with a blower instead of the blowers 60, and the blower may generate wind that moves the heated air near the heat radiator 12. If the volume required for the blowers is permits, the electronic equipment 100 may be equipped with the blowers 60 and the blower of the heat radiation device 1.

As shown in FIG. 2B, in the embodiment, the heat transfer section 111 and the support plate 15 are located at a right angle therebetween, and the lower part of the support plate 15 is in contact with the heat receiver 11 (heat transfer section 111). However, the configuration is not limited to this. The heat pipe 13 connects the heat receiver 11 and the heat radiator 12 separated from the heat receiver 11, and contacts with the support plate 15.

In the heat receiver 11, a pair of rail-like protrusions 1111 (guides) are located on the top surface 111s (first surface), which is the opposite side of the heat transfer section 111 from the side with the protruding section 112, and the heat pipe 13 extends between said protrusions 1111. The sides of the protrusions 1111 and the top surface 111s between the sides are joined to the heat pipe 13 by the joint 114. The height of the protrusions 1111 is preferrably the same as the height of the heat pipe 13, but may be higher or lower. This configuration increases the area where heat is transferred by the sides of the protrusions 1111 covering both sides of the heat pipe 13 (including the case where the covering is imperfect due to the protrusions 1111 being lower than the heat pipe 13 as described above, etc.), and also decreases the area where said heat pipe 13 is in direct contact with the air. The heat transfer section 111 may have a groove on the top surface 111s instead of the pair of protrusions 1111 as the guides. The shape of the top surface 111s between the protrusions 1111 or the shape of the inside of the groove may be adapted to the outer shape of the heat pipe 13. The joint 114 may be embedded in part or all of the gap between the heat pipe 13 and the heat transfer section 111.

The joint 114 is a high thermal conductor (thermally conductive joint). This allows heat to be passed quickly from the heat receiver 11 to the heat pipe 13. Such joint 114 is a member that includes a conductive metal or the like in a conductive manner, and has a thermal conductivity of at least 10 W/(m·K) or more, for example, a solder. Alternatively, the joint 114 may be a brazing material with thermal conductivity of a same degree as that of a solder or a conductive adhesive containing metal fillers (such as silver).

The heat pipe 13 has a pipe made of a material with high thermal conductivity, such as copper, having a capillary structure inside the hollow structure, and a volatile working fluid sealed in the hollow structural portion of said pipe. This working fluid evaporates at the heat source side, absorbs latent heat, moves quickly along the capillary to the heat sink side, and thereafter condenses and releases latent heat to facilitate heat transfer. The cross-sectional outline of the pipe is circular, or wide and flat. Due to this structure, the heat pipe 13 has a significantly large heat transport efficiency (e.g., 1 to 2 digits or more, e.g., 10000 W/(m·K) or higher) compared to the heat receiver 11 and the heat radiator 12, which have higher heat conductivities described above. Therefore, the heat pipe 13 allows the heat receiver 11 to quickly release heat obtained from the heat radiation target 20 to the heat radiator 12. The heat pipe 13 has a bend 131, a straight section 132 connecting to one end of the bend 131, and a straight section 133 connecting to the end opposite to said one end. The straight section 132 (contact section) is in contact with the heat receiver 11 (located on the top surface 111s) and thereby heat is transferred from the heat receiver 11 to the heat pipe 13. The straight section 133 is in contact with the heat radiator 12, and heat is transferred from the heat pipe 13 to the heat radiator 12. In these sections, a minimum length (reference minimum) is usually required to ensure adequate heat transfer between the straight sections 132, 133 (working fluid) and the heat receiver 11 and the heat radiator 12.

The bend 131 has a curved shape (not a fold, for example, the reference minimum radius is three times the outside diameter of the cylindrical heat pipe or the thickness of the flat tube) with a radius of curvature R (reference minimum radius) which is equal to or greater than the minimum necessary for the heat receiver 11 and the heat radiator 12 not to interfere with the movement of the working fluid in the heat pipe 13. The bend 131 bends 90 degrees (bend angle) from the direction along the top surface 111s of the straight section 132 and changes its direction to the direction away from said top surface 111s (that is, the direction away from the heat radiation target 20 in the embodiment, since the reference plane of top surface 111s (excluding uneven portions such as protrusions 1111) is parallel to the protruding surface 112s of the protruding section 112), and the bend 131 is connected to the straight section 133 oriented substantially perpendicular to the top surface 111s to transfer heat from the heat receiver 11 to the heat radiator 12. This bend 131 is located floating from the surface of the heat transfer section 111. In the heat radiation device 1, the joint 114 is located between the heat transfer section 111 and the bend 131 and is bonded to each of them, so that the heat receiver 11 follows the bend of the bend 131 and contacts the bend 131, and the heat pipe 13 and the heat receiver 11 are physically and thermally connected. The “follow” here means that the distance between each position of the bottom of the bend 131 (in the case of cylindrical shape, the line forming the lowest part) and the heat receiver 11 is at least in a partial range, continuously or intermittently at multiple points, less than or equal to a reference distance that is sufficiently small (e.g., 10% or less, more preferably 2 to 3% or less) relative to the radius of curvature R. At least part of this following portion contacts, i.e., the distance is zero (physically connected), so that heat can be transferred quickly from the heat receiver 11 to the bend 131 (thermally connected).

In a plan view of the heat transfer section 111 viewed from above (opposite side to the heat radiation target 20 of the heat radiation device 1, here, in the direction substantially perpendicular to the protruding surface 112s in contact with the heat radiation target 20), the protrusions 1111 are extending below the position of the bend 131, thereby limiting the joint 114 to between said protrusions 1111 and preventing the joint 114 from protruding outwardly. The height of protrusions 1111 in this area may be the same as the height of protrusions 1111 in the area contacting the straight section 132, or it may be higher or lower.

In such a way, since the bend 131 is in direct contact with the heat receiver 11 to allow heat conduction (thermal connection), the straight section 132 may be shorter than the conventional length (reference minimum). For example, it is sufficient that the length of the heat pipe 13 connected to said heat transfer section 111, i.e., the sum of the lengths of the straight section 132 and the bend 131 (or the length in a plan view) is equal to or greater than the above reference minimum. When the reference minimum radius is too large to ignore relative to the sizes of the heat radiation target 20 and the heat receiver 11, the plan view size of the heat radiation device 1 is suppressed to increase by the size of the bend 131, by such a configuration that the bend 131 also becomes a contact portion with the heat receiver 11.

Here, a groove extends in the support plate 15 and the heat pipe 13 extends in said groove. The depth of the groove is about the thickness of the heat pipe 13 (e.g., diameter of the circular outer section), where the heat pipe 13 and each heat radiation fin of the heat radiator 12 are in contact. Alternatively, the heat pipe 13 may penetrate the plate surface (penetration here is not limited to the case of a closed area surrounded entirely by the plate surface, but may be in the form of a cutout that is partially open at the plate boundary) and contact with the plate surface of each heat radiation fin, depending on the orientation of the plate surface. The cross-sectional shape of the bottom of the groove substantially perpendicular to the direction along said groove may match the outer shape of heat pipe 13 (i.e., may be semi-circular). Alternatively, the gap between the wall surface of said groove and the heat pipe 13 in the groove may be filled by the joint 114 (which may be the same as the above thermally conductive joint). In these cases, the support plate 15 itself may also function as part of the heat radiator 12, and some heat is also transferred through the support plate 15 to each heat radiation fin of the heat radiator 12.

Since the lateral surface of the heat transfer section 111 is in contact with the lower end portion of the support plate 15, the heat pipe 13 has at least part of its end in a plan view in contact with the plan view boundary position of the heat transfer section 111 (on or inside the boundary line). In other words, the heat pipe 13 does not protrude significantly from the plan view range of the heat transfer section 111 (heat receiver 11), enabling a more compact arrangement than conventional structures. Furthermore, a high percentage of heat pipe 13 is in contact with the heat transfer section 111, support plate 15 or heat radiator 12, and the area directly exposed to the air is small. In particular, the fact that no part protrudes from the heat receiver 11 in a plan view (less than conventional structures) makes it difficult for the heat pipe 13 to directly face the air flow (wind) to the blower 60 above. As a result, this heat radiation device 1 radiates less heat directly into the air from the heat pipe 13 than conventional structures. In the heat pipe 13, the larger the temperature gradient between the heat receiver 11 (the part in contact with the heat transfer section 111) and the heat radiator 12 is, the more efficiently heat is transported. Thus, if there is a lot of heat radiation into the air in the middle of the heat pipe 13, this temperature gradient is disturbed and heat transport efficiency decreases. Therefore, this heat radiation device 1 has a structure that facilitates higher heat radiation efficiency than conventional structures.

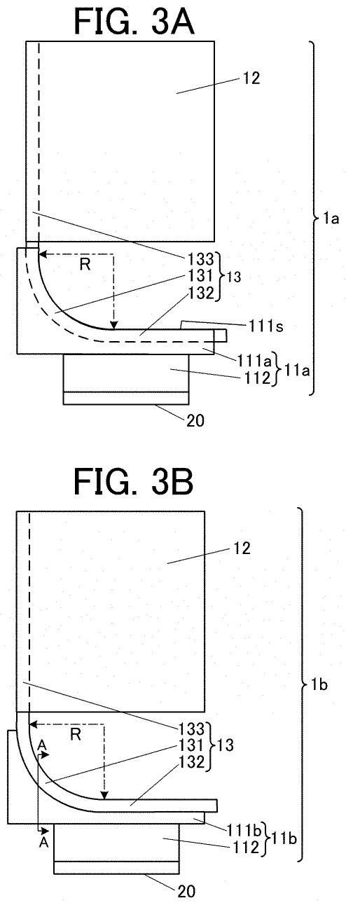

FIG. 3A is a lateral view of a heat radiation device 1a in a second embodiment. FIG. 3B is a lateral view of a heat radiation device 1b in a third embodiment.

In the heat radiation device 1a shown in FIG. 3A, the top surface 111s of the heat receiver 11a is curved along the bend 131 and is in contact with the bend 131 directly or through a thin layer of joint, thereby being physically and thermally connected to the bend 131. In such way, the heat transfer section 111a (base) itself has (follows) a curved surface portion that matches the shape of the heat pipe 13 along the direction of extension, including the bend 131, so that the heat receiver 11 and the heat pipe 13 are easily joined as usual and heat is transferred to the heat pipe 13 at the bend 131 securely and quickly. In this case, the portion of the top surface 111s corresponding to the bend 131 in the left-right direction of FIG. 3A may be curved entirely in the depth direction of FIG. 3A or may protrude from the flat surface only in a portion including the range along the heat pipe 13 in the top surface 111s, for example, may protrude from the flat surface only in a range of the protrusions 1111 and the area therebetween and may be curved (follow) along the heat pipe 13.

In the heat radiation device 1b shown in FIG. 3B, the heat transfer section 111b of the heat receiver lib does not have a groove. The heat pipe 13 located along the curved shaped heat transfer section 111b along (that follows) the bend 131 may be in contact with said section 111b either directly or via the joint 114.

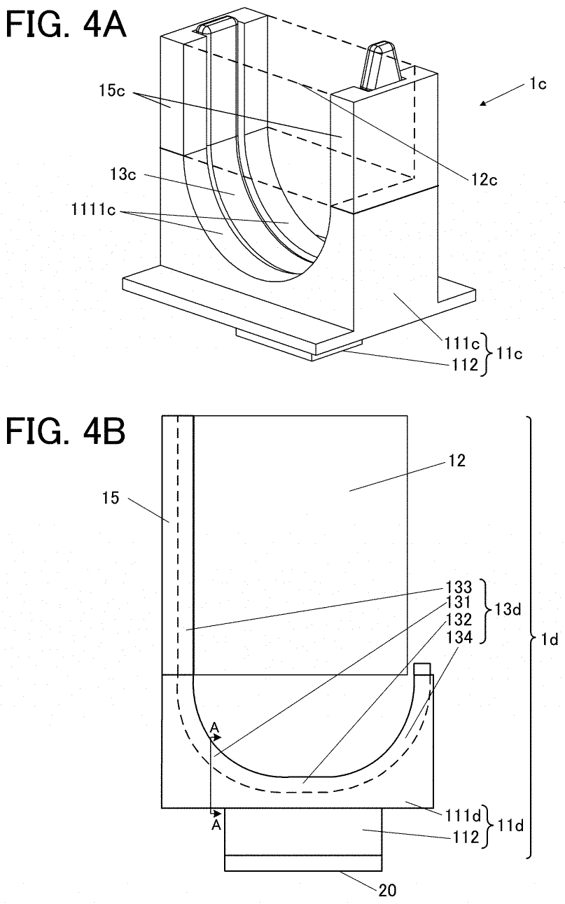

FIG. 4A is a perspective view showing a heat receiver 11c and a heat pipe 13c in a heat radiation device 1c in a fourth embodiment. FIG. 4B is a lateral view of a heat radiation device 1d in a fifth embodiment.

As shown in FIG. 4A, the heat pipe 13c of the heat radiation device 1c is in a U-shape which is bent 180 degrees. The heat transfer section 111c of the heat receiver 11c has two rows of protrusions 1111c along said U-shape and a groove between them into which the heat pipe 13c fits (a groove which has a shape following the heat pipe 13c and contacts the heat pipe 13c). In this case, the heat pipe 13c may receive and absorb heat from the heat transfer section 111c near the central portion from the bottom of the U-shape to the bends on both end sides in the groove between the two rows of protrusions 1111c, and the heat may flow through the bends on both end sides and radiate to the support plates 15c and the heat radiator 12c. That is, a common heat radiator 12c may be located over both ends of the heat pipe 13c (support plates 15c on both sides), as shown by the dashed lines, or there may be multiple heat radiators 12c, respectively separately contacting both ends of the heat pipe 13c (support plates 15c on both sides). In this shape, the length of the heat pipe 13c in contact with the heat receiver 11c relative to the area of the heat receiver 11c in a plan view is increased from conventional structures. This allows more efficient heat transfer to the heat radiator 12c. Also, the heat pipe 13c is exposed to the air only on the internal surface side of the bend, leading to low exposure to wind, and heat is more efficiently transferred from the heat receiver 11c to the heat radiator 12c.

Alternatively, as shown in FIG. 4B, the heat pipe 13d of the heat radiation device 1d in the fifth embodiment may be bent 180 degrees in total, 90 degrees each at the bends 131 and 134 having a straight section 132 therebetween. The heat transfer section 111d has a U-shaped top surface to match (follow) the shape of heat pipe 13d and is in contact with said bends 131 and 134 directly or through a joint. This increases the length of the heat pipe 13d in contact with the heat receiver 11d relative to the area of the heat receiver 11d in a plan view from conventional structures. The heat pipe 13d has a j-shape connected at one end to a straight section 133 that extends straight upward. The straight section 133 is fixed to the support plate 15 and transfers heat to the heat radiator 12. In this case, it is desirable that the heat pipe 13d does not have a structure or working fluid that is easily dependent on vertical movement, since the working fluid does not switch monotonically between rising and falling during heat transport and return.

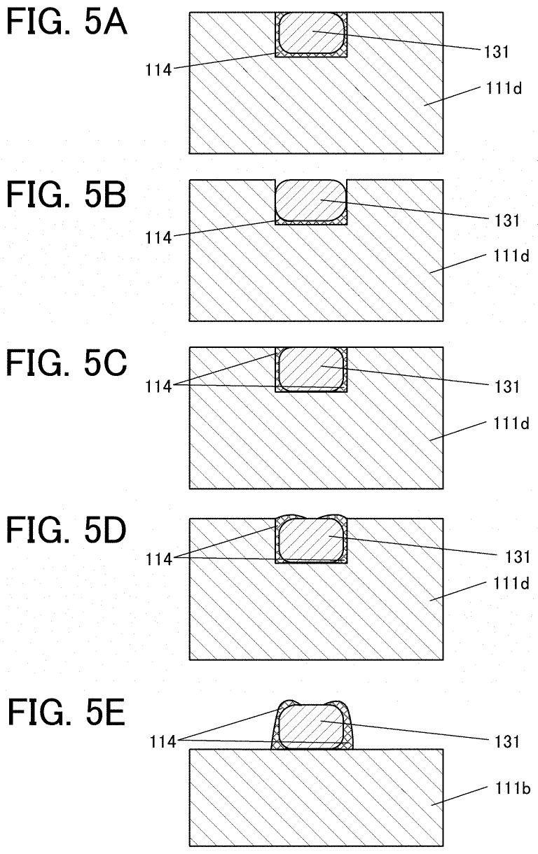

FIGS. 5A to 5E are views showing the cross section at the section line AA of FIG. 4B or the cross section at the section line AA of FIG. 3B.

For example, as shown in FIG. 5A, the bend 131 of heat pipe 13d may be entirely in contact with the heat transfer section 111d via the joint 114 in the groove. As shown in FIG. 5B, a portion of heat pipe 13d, e.g., the bottom surface, may be in contact with the heat transfer section 111d via the joint 114, and the side surface of heat pipe 13d may be in direct contact with the heat transfer section 111d. On the contrary, as shown in FIG. 5C, the heat transfer section 111d and the heat pipe 13d (bend 131) may be in direct contact with each other at the bottom of the groove, while at the sides of the groove, the heat transfer section 111d and the heat pipe 13d (bend 131) may be in contact via the joint 114.

Alternatively, as in FIG. 5D, the joint 114 may contact the top side of the heat pipe 13d (outside of the groove, that is, other than the position between the heat transfer section 111d and the heat pipe 13d). Furthermore, as shown in FIG. 5E, if there is no projection of the heat transfer section 111b along the sides of the heat pipe 13, the bottom of the heat pipe 13 may be in direct contact with the heat transfer section 111b, and the sides of the heat pipe 13 may be joined to the raised joint 114 on the heat transfer section 111b.

As described above, the heat radiation device 1 in the above embodiment has a heat receiver 11 configured to be in contact with the heat radiation target 20, a heat radiator 12 that radiates heat into the air, and a heat pipe 13 that transfers heat from the heat receiver 11 to the heat radiator 12. The heat pipe 13 has a bend 131 that bends in a direction away from the heat radiation target 20, and the heat receiver 11 has a section that follows at least part of the bend 131 and is in contact with the bend 131.

In such a way, the heat radiation device 1 can transfer heat from the heat receiver 11 to the bend 131 that bends in the direction away from the heat radiation target 20. Therefore, even if the length of the straight section 132, which is conventionally required on the top surface 111s, is shortened, heat radiation can be performed efficiently by transferring heat according to the heat transfer capability of the heat pipe 13 from the heat receiver 11 to the heat pipe 13. This also means that the bend 131 does not have to extend far outside of the heat receiver 11 in a plan view, making the size of the heat radiation device 1 more compact without lowering the amount of heat radiation, and improving heat radiation efficiency. Furthermore, since the heat pipe 13 does not extend far outside of the heat receiver 11, the area exposed to air is reduced and proper maintenance of the temperature gradient between the heat receiver 11 and the heat radiator 12 of said heat pipe 13 is facilitated, resulting in more efficient heat transport.

The heat receiver 11 includes the base including a heat transfer section 111 and a protruding section 112, and a joint 114. The joint 114 may be in contact with at least part of the bend 131. This ensures that the heat radiation device 1a can reliably transfer heat directly from the relatively fixed heat receiver 11 to the bend 131. In addition, since heat transfer from the heat receiver 11 to the heat pipe 13 is not limited to the straight section 132, efficient heat transfer is possible without wasting space in the bend 131 due to the radius of curvature R.

The base (heat transfer section 111) also may have a curved section at least part of which follows the at least part of the bend 131, and the at least part of the curved section may be in contact (directly and/or via a thin layer of joint 114) with the heat pipe 13. By matching the shape of the heat transfer section 111 itself to the bend shape of the bend 131, heat can be transferred from the heat receiver 11 to the heat pipe 13 directly or to the close range with high thermal conductivity even in that section, making the heat transport by the heat pipe 13 more compact in a plan view size.

The joint 114 may also be located in the gap between at least part of the bend 131 and the base (heat transfer section 111) and may be in contact with the bend 131 and the heat transfer section 111. At least part of these are connected by the joint 114, which has a high thermal conductivity (rate). If the pipe diameter of the heat pipe 13 is small and accordingly the radius of curvature R of the bend 131 is not so large, the space can be easily physically and thermally connected between the bend 131 and the heat transfer section 111 by filling the above gap with the joint 114. This allows heat to be transferred between the heat receiver 11 and the bend 131 even if the top surface 111s of the heat receiver 11 merely has a simple flat surface or guide section. Thus, the heat transport efficiency is not reduced even if the straight section 132 is shortened to make the heat radiation device 1 smaller than conventional structures.

The joint 114 is a solder, a brazing material or a conductive adhesive. By utilizing the conventionally used materials with high thermal conductivity mentioned above as the joint 114, it is possible to make the heat receiver 11 follow the bend 131 easily at low cost and to physically and thermally connect the bend 131 to the heat receiver 11.

The heat pipe 13 also has a straight section 132 connecting to one end of the bend 131, and the straight section 132 is located on the heat transfer section 111. The heat radiation device 1 can still provide adequate heat transport in a more compact manner even if this straight section 132 is shortened while maintaining this conventional positional relationship, as described above.

The heat receiver 11 (heat transfer section 111) may have protrusions 1111 covering both sides of said heat pipe 13 along the extending direction of the heat pipe 13. This allows heat to be transferred to said heat pipe 13 from three directions, not just from the bottom side of the heat pipe 13, thereby improving transport efficiency. On the other hand, the exposed area of heat pipe 13 to the outside (air) can be reduced. Thus, unnecessary heat radiation at other than the heat radiator 12 can be suppressed. This maintains a proper temperature gradient between the heat receiver 11 side and the heat radiator 12 side in the heat pipe 13, resulting in more efficient heat transport. The consumption amount of the joint 114 can be kept within an appropriate range since the joint 114 can be restrained from protruding from between the protrusions 1111.

In addition, at least part of the bend 131 is within the range of the heat receiver 11 in a plan view of the heat radiation target 20 from above (from the side of heat radiation device 1). In other words, the at least part of the bend 131 overlaps at least part of the heat receiver 11 in the plan view. At least part of the at least part of the band 131 is in contact with the heat receiver 11.

Thus, by including the bend 131 as much as possible in the range of the heat receiver 11 in a plan view, a more compact heat radiation device 1 than conventional structures can be obtained, while reducing the loss of efficiency of heat transport from the heat receiver 11 to the heat radiator 12.

The bend 131 may have a bend angle of 90 degrees. This allows the heat radiator 12 to be placed directly above the heat receiver 11 without significantly protruding from the range of the heat receiver 11 in a plan view, thus enabling effective heat transport and radiation through efficient use of space.

The heat pipe 13 also has one end of the bend 131 directed to a direction substantially perpendicular to the top surface 111s, and at least part of the one end is located on or inside the boundary line of said top surface 111s (heat receiver 11) in a plan view of the top surface 111s seen from above. Thus, since the bend 131, or the heat pipe 13, stays within the range of the heat receiver 11 in a plan view without clearly protruding outward, the heat radiation device 1 can be made compact without taking up much space while maintaining the heat transport volume.

The electronic equipment 100 of the embodiment is equipped with the heat radiation device 1 described above and a heat radiation target 20 (here, optical system 40 and/or control circuit 50) that is in contact with the heat receiver 11 of said heat radiation device 1. By using the compact heat radiation device 1 to radiate heat in the electronic equipment 100, it is possible to appropriately suppress the increase in the overall size of the electronic equipment 100 and generation of unnecessary space inside the electronic equipment 100 while preventing overheating of the electronic equipment 100.

The present disclosure is not limited to the above embodiments, and various changes can be made. For example, in the above embodiments, the heat pipe 13 is described as being in contact with the top surface 111s of the heat receivers 11, 11ai to 11d and as being located between the protrusions 1111 (or in a groove) extending on the top surface 111s, but the heat pipe 13 may also penetrate into the interior of the heat receiver 11. In this case, the bend 131 may be entirely buried or, if part of the bend 131 is outside the heat receiver 11, the outside portion may be joined to the top surface 111s by the joint 114.

In the above embodiment, the heat receiver 11 follows to the entire bend 131 to join the top surface 111s. However, the present disclosure is not limited to this. The top surface 111s may be joined so that the heat receiver 11 follows only part of the bend 131. The portion of the heat receiver 11 that follows and contacts the bend 131 does not have to be a continuous part and may be divided into multiple parts. In other words, at least part of the bend 131 is connected to the heat receiver 11, allowing heat to be transferred more efficiently from the heat receiver 11 to the heat pipe 13 in a more compact range than conventional structures.

Also, the heat receiver 11 may not be flat or curved, but rather a folded shape (for example, a concave structure with multiple faces aligned asymptotically to the bend 131 and following said bend 131, or a staircase shape with each corner following the bend 131), and may be in contact with the bend 131 at intervals. The contact area may be increased by embedding, with the joint 114, part or all of the portion not in direct contact.

The joint 114 may be other than the solder, brazing material or conductive adhesive. As long as the thermal conductivity is high, electrical conductivity and the like need not be considered, and an appropriate material may be selected.

The joint 114 may join only the straight section 132 to the heat receiver 11, while the bend 131 and the heat transfer section 111 are not joined but merely touching. In this case, the structure may be such that the bend 131 and the heat transfer section 111 are pressed against each other to prevent separation due to vibration or distortion over time.

In the above embodiment, the straight section 132 is described as being in contact with the top surface 111s of the heat receiver 11 as in conventional structures. However, instead of the straight section 132, there may be provided an upward bend as described above, or a section meandering in any orientation, in a plane along the top surface 111s or in a plane substantially perpendicular to the top surface 111s, etc.

In the above embodiment, the bend 131 is described as a 90-degree or a total of 180-degree bend. However, the present disclosure is not limited to this. The bend 131 may be a bend of any other angle. The arrangement and shape of the fins may be adjusted accordingly. The radius of curvature R with the bend 131 does not have to be constant. The radius of curvature R(θ) may vary according to the angle θ in the range of radius of curvature which is the reference minimum radius or greater.

In the above embodiment, the protrusions 1111 are described as a pair located on both sides of the heat pipe 13, but there may be a single protrusion 1111 on only one side of the heat pipe 13.

In the above embodiment, the straight section 132 is shorter than conventional structures, and at least part of one end of the bend 131 (straight section 133) is described as being inside or on the boundary of the heat receiver 11 in a plan view. However, the present disclosure is not limited to this. Even without shortening the straight section 132, the amount of heat transport for heat radiation can be increased by physically/thermally connecting the bend 131 to the top surface 111s of the heat receiver 11. Alternatively, the plan view position of the straight section 133 may be outside the plan view range of the top surface 111s while somewhat reducing the plan view area of the top surface 111s to make the size smaller than conventional structures.

In the above embodiment, a projection device was taken as an example of the electronic equipment 100. However, the present disclosure is not limited to this. The electronic equipment 100 may be electronic equipment that can use the heat radiation device 1 to radiate heat from various components such as CPU, graphic board, light emitter (including infrared rays and UV), motors, internal support structures and boards.

As for the other specific configurations, contents and procedures of processing operations shown in the above embodiments, modifications can be appropriately made within the scope of the present disclosure.

Although several embodiments of the present disclosure have been described, the scope of the present disclosure is not limited to the above described embodiments and includes the scope of the present disclosure that is described in the claims and the equivalents thereof.

1. A heat radiation device comprising:
a heat receiver configured to be in contact with a heat radiation target;
a heat radiator that radiates heat into air; and
a heat pipe that transfers heat from the heat receiver to the heat radiator, wherein
the heat pipe includes a bend that bends in a direction away from the heat radiation target, and
the heat receiver includes a section that follows at least part of the bend and is in contact with the bend.

2. The heat radiation device according to claim 1, wherein
the heat receiver includes a base and a joint that joins the base to the heat pipe, and
the joint is in contact with the at least part of the bend.

3. The heat radiation device according to claim 1, wherein
the heat receiver includes a base and a joint that joins the base to the heat pipe, and
the base includes a curved section at least part of which follows the at least part of the bend, and the at least part of the curved section is in contact with the heat pipe.

4. The heat radiation device according to claim 2, wherein the joint is located in a gap between the at least part of the bend and the base, and is in contact with the bend and the base.

5. The heat radiation device according to claim 2, wherein the joint is a solder, a brazing material or a conductive adhesive.

6. The heat radiation device according to claim 2, wherein
the heat pipe includes a straight section connected to one end of the bend, and
the straight section is located on the base.

7. The heat radiation device according to claim 1, wherein the heat receiver includes a guide that covers both lateral surfaces of the heat pipe along an extending direction of the heat pipe.

8. The heat radiation device according to claim 1, wherein at least part of the bend is within a range of the heat receiver in a plan view seen from a direction substantially perpendicular to a contact surface with the heat radiation target of the heat receiver, and at least part of the at least part of the bend is in contact with the heat receiver.

9. The heat radiation device according to claim 1, wherein the bend has a bend angle of 90 degrees.

10. The heat radiation device according to claim 1, wherein
in the heat pipe, one end of the bend is directed to a direction substantially perpendicular to a contact surface with the heat radiation target of the heat receiver, and
at least part of the one end is located on or inside a boundary line of the heat receiver in a plan view seen from the direction substantially perpendicular to the contact surface.

11. The heat radiation device according to claim 1, wherein the heat pipe includes bends on respective end sides, and the heat receiver follows each of the bends and is in contact with at least part of each of the bends.

12. An electronic equipment comprising:
the heat radiation device according to claim 1; and
the heat radiation target that is in contact with the heat receiver.
